(19) United States
(12) Patent Application Publication
(10) Pub. No.: US 2018/0358392 A1
(43) Pub. Date: Dec. 13, 2018

(54) IMAGE SENSOR AND FABRICATION METHOD THEREOF

(71) Applicant: UNITED MICROELECTRONICS CORP., Hsin-Chu City (TW)

(72) Inventor: Cheng-Yu Hsieh, Hsinchu County (TW)

(21) Appl. No.: 15/616,904

(22) Filed: Jun. 7, 2017

(51) Int. Cl. H01L 27/146

(52) U.S. Cl. CPC H01L 27/1463; H01L 27/14643; H01L 27/14621; H01L 27/1464; H01L 27/14636; H01L 27/14685; H01L 27/14698; H01L 27/14627

(57) ABSTRACT

An image sensor is disclosed. The image sensor includes a substrate having a frontside surface and a backside surface. A plurality of photoelectric transducer elements is disposed on the frontside surface. A dielectric isolation structure extends into the substrate from the frontside surface so as to isolate the plurality of photoelectric transducer elements from one another. A grid structure is disposed on the backside surface. The grid structure has an embedded portion extending into the substrate from the backside surface. The embedded portion of the grid structure is aligned with and in direct contact with the dielectric isolation structure.

### BACKGROUND OF THE INVENTION

### 1. Field of the Invention

The present invention relates generally to the field of image sensors. More particularly, the present invention relates to a backside illumination (BSI) image sensor and a method for fabricating the same.

### 2. Description of the Prior Art

Backside illumination (BSI) image sensors are known in the art. BSI image sensors are CMOS image sensors in which light enters from a back side of a substrate, rather than the front side. BSI sensors are capable of capturing more of an image signal than front side illumination sensors due to a reduced reflection of light.

In the formation of the BSI image sensors, photo diodes and logic circuits are formed on a silicon substrate of a wafer, followed by the formation of an interconnect structure on a front side of the silicon chip. The image sensors in the BSI image sensor chips generate electrical signals in response to the stimulation of photons.

To reduce the optical cross-talks of the light received by different image sensors, metal grids are typically formed to isolate the light.

### SUMMARY OF THE INVENTION

It is one object of the invention to provide an improved backside illumination (BSI) image sensor and the fabrication method thereof to reduce optical or electrical cross-talks and to increase chief-array angle window for the sensor design.

According to one aspect of the invention, an image sensor is disclosed. The image sensor includes a substrate having a frontside surface and a backside surface, a plurality of photoelectric transducer elements disposed on the frontside surface, a dielectric isolation structure extending into the substrate from the frontside surface so as to isolate the plurality of photoelectric transducer elements from one another, and a grid structure disposed on the backside surface. The grid structure comprises an embedded portion extending into the substrate from the backside surface. The embedded portion of the grid structure is aligned with and in direct contact with the dielectric isolation structure.

According to another aspect of the invention, a method for fabricating an image sensor is disclosed. A substrate having a frontside surface and a backside surface is provided. A plurality of photoelectric transducer elements is disposed on the frontside surface. A dielectric isolation structure extends into the substrate from the frontside surface so as to isolate the plurality of photoelectric transducer elements from one another. The dielectric isolation structure is recess etched from the backside surface so as to form a recessed trench region in the backside surface. A grid material layer is deposited on the backside surface. The recessed trench region is completely filled with the grid material layer. The grid material layer is subjected to a lithographic process and an etching process so as to form a grid structure on the backside surface.

According to still another aspect of the invention, a method for fabricating an image sensor is disclosed. A substrate having a frontside surface and a backside surface is provided. A plurality of photoelectric transducer elements is disposed on the frontside surface. A dielectric isolation structure extends into the substrate from the frontside surface so as to isolate the plurality of photoelectric transducer elements from one another. The dielectric isolation structure is recess etched from the backside surface so as to form a recessed trench region in the backside surface. A grid material layer is deposited on the backside surface. The recessed trench region is completely filled with the grid material layer. The grid material layer is subjected to a chemical mechanical polishing process so as to form a grid structure in the backside surface.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view of a backside illumination (BSI) image sensor showing a portion of the layout of the grid structure on the backside surface according to one embodiment of the invention.

FIG. 2 is a schematic, cross-sectional view taken along line I-I′ in FIG. 1.

FIG. 3 to FIG. 7 are schematic, cross-sectional diagrams showing a method for fabricating a BSI image sensor according to another embodiment of the invention.

FIG. 8 to FIG. 11 are schematic, cross-sectional diagrams showing a self-aligned method for forming the grid structure on the backside surface of the substrate according to another embodiment of the invention.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the invention.

Before the further description of the preferred embodiment, the specific terms used throughout the text will be described below.

The term “etch” is used herein to describe the process of patterning a material layer so that at least a portion of the material layer after etching is retained. For example, it is to be understood that the method of etching silicon involves patterning a mask layer (e.g., photoresist or hard mask) over silicon and then removing silicon from the area that is not protected by the mask layer. Thus, during the etching process, the silicon protected by the area of the mask will remain.

In another example, however, the term “etch” may also refer to a method that does not use a mask, but leaves at least a portion of the material layer after the etch process is complete. The above description is used to distinguish between “etching” and “removal”. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The terms “forming”, “depositing” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

According to various embodiments, for example, deposition may be carried out in any suitable known manner. For example, deposition may include any growth, plating, or transfer of material onto the substrate. Some known techniques include physical vapor deposition (PVD), chemical vapor deposition (CVD), electrochemical deposition (ECD), molecular beam epitaxy (MBE), atomic layer deposition (ALD), and plasma enhanced CVD (PECVD).

The term “substrate” described in the text is commonly referred to as a silicon substrate. However, the substrate may also be any semiconductor material, such as germanium, gallium arsenide, indium phosphide and the like. In other embodiments, the substrate may be non-conductive, such as glass or sapphire wafers.

The present invention pertains to a backside-illuminated (BSI) image-sensor device. The BSI image-sensor device includes a charge-coupled device (CCD), a complementary metal oxide semiconductor (CMOS) image sensor (CIS), an active-pixel sensor (APS) or a passive-pixel sensor. The image-sensor device may include additional circuitry and input/outputs that are provided adjacent to the grid of pixels for providing an operation environment of the pixels and for supporting external communication with the pixels.

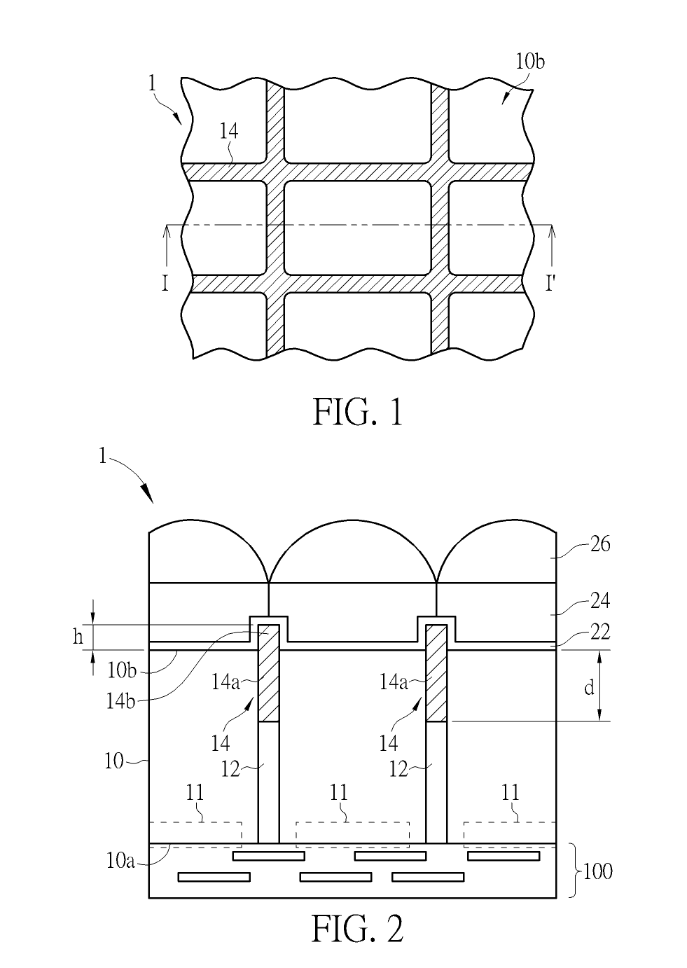

Please refer to FIG. 1 and FIG. 2. FIG. 1 is a schematic top view of a backside illumination (BSI) image sensor showing a portion of the layout of the grid structure on the backside surface according to one embodiment of the invention. FIG. 2 is a schematic, cross-sectional view taken along line I-I′ in FIG. 1.

As shown in FIG. 1 and FIG. 2, the image sensor 1 includes a substrate 10 having a frontside surface 10a and a backside surface 10b that is opposite to the frontside surface 10a. Photoelectric transducer elements 11 are disposed on and in the frontside surface 10a. According to one embodiment of the invention, each of the photoelectric transducer elements 11 may comprise a photodiode in the substrate 10. A dielectric isolation structure 12 extends into the substrate 10 from the frontside surface 10a so as to isolate the photoelectric transducer elements 11 from one another. According to one embodiment of the invention, the dielectric isolation structure 12 may be a deep trench isolation structure.

According to one embodiment of the invention, an interconnect scheme 100 may be fabricated on the frontside surface 10a. For the sake of simplicity, detailed structures of some well-known devices such as photodiode gates, reset transistors, source follower transistors, or transfer transistors are not shown in the figures.

The image sensor 1 further includes a grid structure 14 disposed on and in the backside surface 10b. According to one embodiment of the invention, the grid structure 14 comprises an embedded portion 14a extending into the substrate 10 from the backside surface 10b. The embedded portion 14a of the grid structure 14 is aligned with and in direct contact with the dielectric isolation structure 12. According to one embodiment of the invention, the grid structure 12 comprises a protruding portion 14b above the backside surface 10b. The protruding portion 14b is structurally integral with the embedded portion 14a.

According to one embodiment of the invention, the protruding portion 14b has a height h above the backside surface 10b, for example, the height h ranges between 200˜500 nanometers. According to one embodiment of the invention, the embedded portion 14a has a depth d under the backside surface 10b, for example, the depth d is less than 1.5 micrometers. According to one embodiment of the invention, for example, the embedded portion 14a may have a depth d ranging between 1.4 micrometers and 1.5 micrometers, but is not limited thereto.

According to one embodiment of the invention, the grid structure 14 may comprise metal such as tungsten, aluminum, or metal oxide such as aluminum oxide (Al₂O₃) or titanium oxide (TiO₂). According to another embodiment of the invention, the grid structure may comprise silicon.

According to one embodiment of the invention, a passivation layer 22 conformally covers the backside surface 10b of the substrate 10 and the protruding portion 14b of the grid structure 14. A color filter 24 may be disposed on the passivation layer 22. An array of micro-lenses 26 maybe disposed on the color filter 24. The passivation layer 22 may act as an anti-reflection layer.

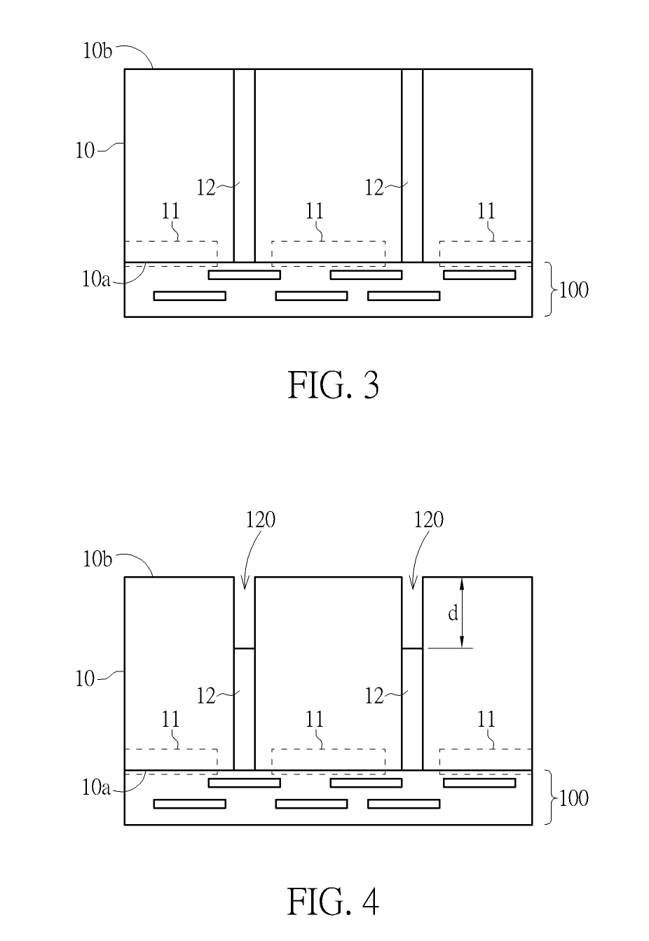

Please refer to FIG. 3 to FIG. 7. FIG. 3 to FIG. 7 are schematic, cross-sectional diagrams showing a method for fabricating an image sensor according to another embodiment of the invention. As shown in FIG. 3, a substrate 10 having a frontside surface 10a and a backside surface 10b is provided. A plurality of photoelectric transducer elements 11 is disposed on the frontside surface 10a. A dielectric isolation structure 12 extends into the substrate 10 from the frontside surface 10a so as to isolate the photoelectric transducer elements 11 from one another.

For example, to form the dielectric isolation structure 12, deep trenches are formed in the substrate 10 from the frontside surface 10a. A dielectric layer such as silicon oxide is then deposited into the deep trenches. A wafer backside grinding process may be carried out to expose the end surfaces of the dielectric isolation structure 12 from the backside surface 10b, such that the dielectric isolation structure 12 through the entire thickness of the substrate 10.

As shown in FIG. 4, the dielectric isolation structure 12 is recess etched from the backside surface 10b so as to form a recessed trench region 120 in the backside surface 10b. The recessed trench region 120 may have a depth d under the backside surface 10b, for example, the depth d is less than 1.5 micrometers. According to one embodiment of the invention, for example, the depth d may range between 1.4 micrometers and 1.5 micrometers, but is not limited thereto.

As shown in FIG. 5, a grid material layer 140 is deposited on the backside surface 10b. According to one embodiment of the invention, the grid material layer 140 may comprise metal such as tungsten, aluminum, or metal oxide such as aluminum oxide (Al₂O₃) or titanium oxide (TiO₂). According to another embodiment of the invention, the grid structure may comprise silicon. The recessed trench region 120 is completely filled with the grid material layer 140.

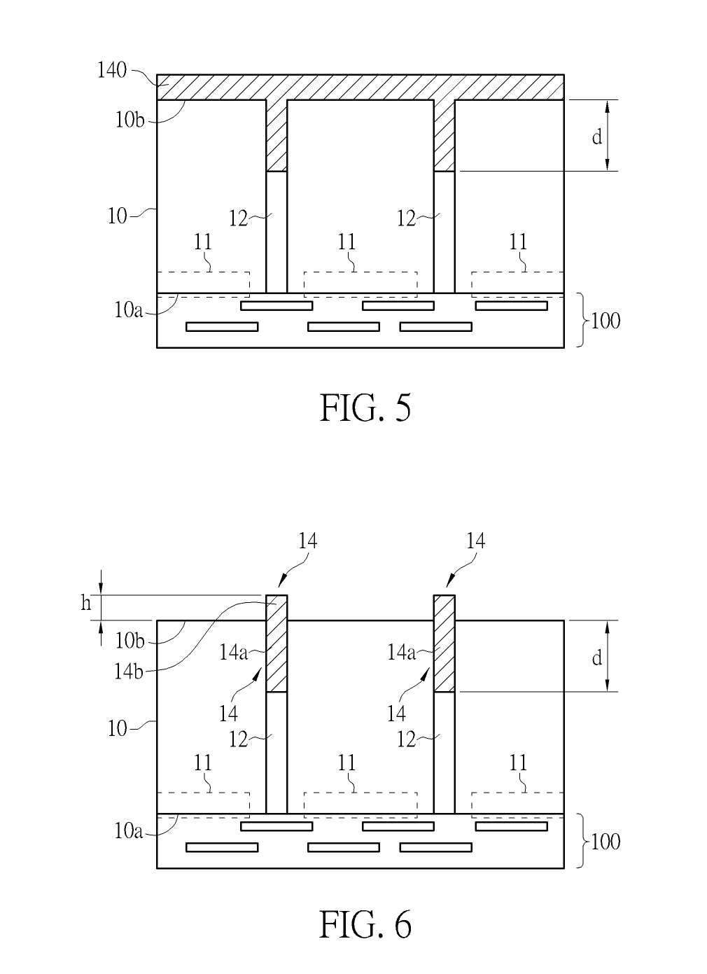

As shown in FIG. 6, the grid material layer 140 is subjected to a lithographic process and an etching process so as to form a grid structure 14 on the backside surface 10b. According to one embodiment of the invention, the grid structure 14 comprises a protruding portion 14b above the backside surface 10b and an embedded portion 14a within the recessed trench region 120. The embedded portion 14a is aligned with and in direct contact with the dielectric isolation structure 12. The protruding portion 14b is structurally integral with the embedded portion 14a.

According to one embodiment of the invention, the protruding portion 14b has a height h above the backside surface 10b, for example, the height h ranges between 200˜500 nanometers.

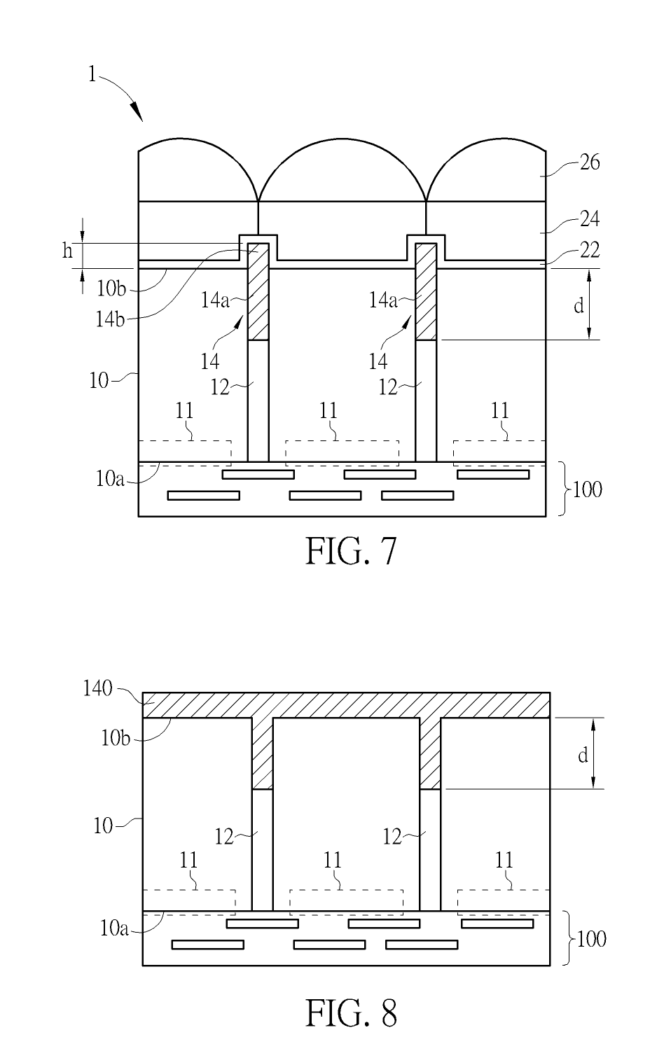

As shown in FIG. 7, a passivation layer 22 is then deposited conformally on the backside surface 10b of the substrate 10 and the protruding portion 14b. The passivation layer 22 may act as an anti-reflection layer. A color filter 24 is then formed on the passivation layer 22. An array of micro-lenses 26 is then formed on the color filter 24.

Please refer to FIG. 8 to FIG. 11. FIG. 8 to FIG. 11 are schematic, cross-sectional diagrams showing a self-aligned method for forming the grid structure on the backside surface of the substrate according to another embodiment of the invention. As shown in FIG. 8, likewise, after forming the recessed trench region 120 as described in FIG. 3 and FIG. 4, a grid material layer 140 is deposited on the backside surface 10b.

According to one embodiment of the invention, the grid material layer 140 may comprise metal such as tungsten, aluminum, or metal oxide such as aluminum oxide (Al₂O₃) or titanium oxide (TiO₂). According to another embodiment of the invention, the grid structure may comprise silicon. The recessed trench region 120 is completely filled with the grid material layer 140.

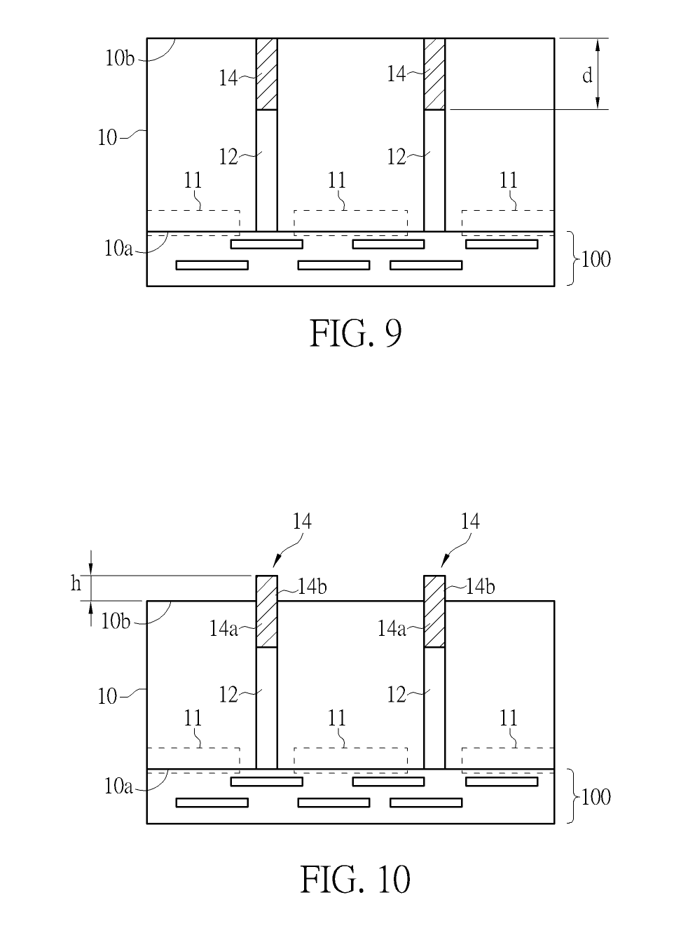

As shown in FIG. 9, the grid material layer 140 is subjected to a chemical mechanical polishing (CMP) process so as to form a grid structure 14 in the backside surface 10b. At this point, the backside surface 10b is exposed and is flush with the exposed end surface of the grid structure 14.

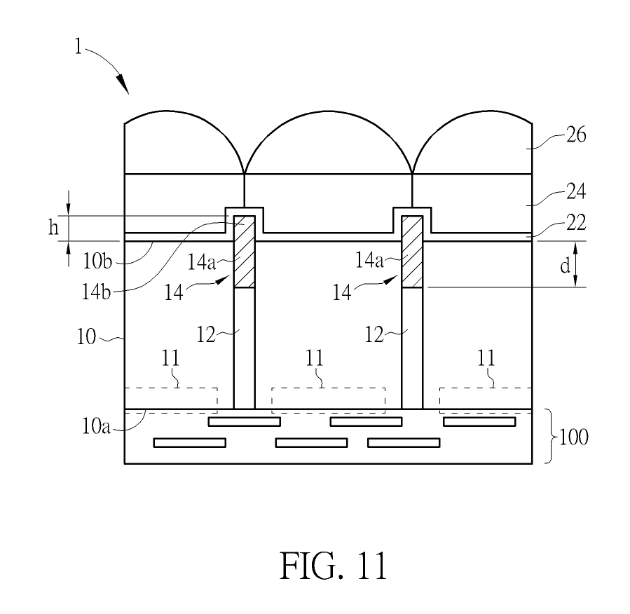

As shown in FIG. 10, the substrate 10 is selectively etched from the baskside surface 10b so as to form a protruding portion 14b of the grid structure 14 above the backside surface 10b. According to one embodiment of the invention, the protruding portion 14b has a height h above the backside surface 10b, for example, the height h ranges between 200˜500 nanometers.

As shown in FIG. 11, a passivation layer 22 is then deposited conformally on the backside surface 10b of the substrate 10 and the protruding portion 14b. The passivation layer 22 may act as an anti-reflection layer. A color filter 24 is then formed on the passivation layer 22. An array of micro-lenses 26 is then formed on the color filter 24.

Those skilled in the art will readily observe that numerous modifications and alterations of the device and method may be made while retaining the teachings of the invention. Accordingly, the above disclosure should be construed as limited only by the metes and bounds of the appended claims.

1. An image sensor, comprising:
a substrate having a frontside surface and a backside surface;
a plurality of photoelectric transducer elements disposed on the frontside surface;
a dielectric isolation structure extending into the substrate from the frontside surface so as to isolate the plurality of photoelectric transducer elements from one another;
a grid structure disposed on the backside surface, wherein the grid structure comprises an embedded portion extending into the substrate from the backside surface, wherein the embedded portion of the grid structure is aligned with and in direct contact with the dielectric isolation structure, wherein the grid structure is made of silicon.

2. The image sensor according to claim 1, wherein the grid structure comprises a protruding portion above the backside surface.

3. The image sensor according to claim 2, wherein the protruding portion is structurally integral with the embedded portion.

4. The image sensor according to claim 2, wherein the protruding portion has a height above the backside surface, and wherein the height ranges between 200˜500 nanometers.

5. The image sensor according to claim 1, wherein the embedded portion has a depth under the backside surface, and wherein the depth is less than 1.5 micrometers.

6. The image sensor according to claim 1, wherein the grid structure comprises metal or metal oxide.

7. (canceled)

8. The image sensor according to claim 2 further comprising:
a passivation layer conformally covering the backside surface of the substrate and the protruding portion.

9. The image sensor according to claim 8 further comprising:
a color filter on the passivation layer; and
an array of micro-lenses on the color filter.

10. The image sensor according to claim 1, wherein each of the plurality of photoelectric transducer elements comprises:
a photo-diode in the substrate.

11. A method for fabricating an image sensor, comprising:
providing a substrate having a frontside surface and a backside surface, wherein a plurality of photoelectric transducer elements is disposed on the frontside surface, wherein a dielectric isolation structure extends into the substrate from the frontside surface so as to isolate the plurality of photoelectric transducer elements from one another;
recess etching the dielectric isolation structure from the backside surface so as to form a recessed trench region in the backside surface;
depositing a grid material layer on the backside surface, wherein the recessed trench region is completely filled with the grid material layer; and
subjecting the grid material layer to a lithographic process and an etching process so as to form a grid structure on the backside surface.

12. The method according to claim 11, wherein the grid structure comprises a protruding portion above the backside surface and an embedded portion within the recessed trench region, wherein the embedded portion is aligned with and in direct contact with the dielectric isolation structure.

13. The method according to claim 12, wherein the protruding portion is structurally integral with the embedded portion.

14. The method according to claim 12, wherein the protruding portion has a height above the backside surface, and wherein the height ranges between 200˜500 nanometers.

15. The method according to claim 12, wherein the recessed trench region has a depth under the backside surface, and wherein the depth is less than 1.5 micrometers.

16. The method according to claim 11 further comprising:
depositing a passivation layer on the backside surface of the substrate and the protruding portion;
forming a color filter on the passivation layer; and
forming an array of micro-lenses on the color filter.

17. The method according to claim 11, wherein the grid material layer comprises metal or metal oxide.

18. The method according to claim 11, wherein the grid material layer comprises silicon.

19. A method for fabricating an image sensor, comprising:
providing a substrate having a frontside surface and a backside surface, wherein a plurality of photoelectric transducer elements is disposed on the frontside surface, wherein a dielectric isolation structure extends into the substrate from the frontside surface so as to isolate the plurality of photoelectric transducer elements from one another;
recess etching the dielectric isolation structure from the backside surface so as to form a recessed trench region in the backside surface;
depositing a grid material layer on the backside surface, wherein the recessed trench region is completely filled with the grid material layer; and
subjecting the grid material layer to a chemical mechanical polishing process so as to form a grid structure in the backside surface.

20. The method according to claim 19 further comprising:
selectively etching the substrate from the baskside surface so as to form a protruding portion of the grid structure above the backside surface.

21. The method according to claim 20 further comprising:
depositing a passivation layer on the backside surface of the substrate and the protruding portion;
forming a color filter on the passivation layer; and
forming an array of micro-lenses on the color filter.

22. The method according to claim 20, wherein the protruding portion has a height above the backside surface, and wherein the height ranges between 200˜500 nanometers.

23. The method according to claim 19, wherein the recessed trench region has a depth under the backside surface, and wherein the depth is less than 1.5 micrometers.
